(19) United States
(12) Patent Application Publication
(10) Pub. No.: US 2003/0218697 A1
(43) Pub. Date: Nov. 27, 2003

(54) Broadband television tuner front end

(76) Inventor: Kovacic Stephen J., Kanata (CA)

Correspondence Address: FREEDMAN & ASSOCIATES, 117 CENTREPOINTE DRIVE, SUITE 350, NEPEAN, ONTARIO, K2G 5X3, CA

(21) Appl. No.: 10/136,308

(22) Filed: May 2, 2002

(51) Int. Cl. H04N 5/50; H03K 3/02; H04N 7/16; H03B 5/32; H04B 1/18

(52) U.S. Cl. 348/731; 331/151; 331/162; 455/191.1; 455/178.1; 455/189.1; 725/151

(57) ABSTRACT

A broadband television receiver front end for receiving a broadband RF input signal and outputting an IF output signal is disclosed. A high pass input filter on the front end attenuates carrier signal frequencies that lie below a cut off frequency of said high pass filter. Thereby advantageously allowing for a number of carrier signals to propagate below the cutoff frequency in such a manner that these signals have a decreased effect on television signals propagating within a television signal band. By high pass filtering on the input a low noise amplifier disposed for receiving a filtered signal from the high pass filter does not amplify noise caused by lower frequency carriers. As a result an amplified signal provided to up-conversion and a down-conversion mixers results in an increased immunity to noise in the output IF signal from the front end.

### FIELD OF THE INVENTION

This invention relates to the area of broadband television tuner circuits and more particularly to the area of a broadband television tuner front end circuits.

### BACKGROUND OF THE INVENTION

Prior to the introduction of cable TV, television signals were broadcast from radio towers. These signals would travel through an unconfined medium—air—prior to being received by antennas electrically coupled to tuners on television sets. Of course, since these signals traveled through the unconfined medium, they were quite susceptible to noise. For example noise arising from other signal sources propagating through the same unconfined medium or noise resulting from environmental effects, such as thunderstorms. These various types of noise would have an adverse effect on the quality of the received TV signal, manifesting themselves as a poor image, poor audio quality, or shadowing in adjacent channels on the TV set. Tuners for receiving broadband television signals received via an antenna are known, such as in Prior Art U.S. Pat. No. 6,281,946.

Analog TV signals are typically transmitted in the frequency range of 50MHz to 810 MHz, where within this range, TV signals are transmitted with a typical TV display resolution of approximately 525 lines. VCRs on the other hand offer lower resolutions, where 240 lines are not uncommon. If noise is present on a TV signal within the TV signal band then the signal will decreased in quality, and may border on quality provided by a VCR; this being unacceptable by demanding consumers.

RF noise is typically a result of other high frequency signals occupying a frequency space above the TV signal band. For instance cellular telephones operate in the GHz frequencies and may contribute to high frequency RF noise received by television tuners.

Prior Art U.S. Pat. Nos. 5,512,958, 5,956,095 and 6,177,964, provide systems and methods for controlling the effects of noise within the TV signal band through filtering of RF within the tuner. Although RF noise is present in systems where the television signal is transmitted and filtering techniques decrease the noise to some extent, the use of an improved transmission medium decreases RF noise significantly within the TV signal band.

With the introduction of a co-axial cable as a broadband TV signal transmission medium, an improved transmission medium is provided which propagates these television signals in such a manner that noise caused by external influences, such as RF noise, is significantly decreased. Co-axial conductors are known to be quite immune to external RF noise because of the shielded nature of the conductor. This introduction of the improved transmission medium led to improvements in television tuners in order to make use of this improved high bandwidth and relatively noise free transmission medium. The improvement in television tuners led to a significant improvement in picture quality, causing the demand for televisions, and therefore TV tuners, to significantly increase. Television tuners are known in the art, such as in Prior Art U.S. Pat. Nos. 5,200,826, 5,428,836, 5,521,650, 5,737,035, 6,037,999, 6,252,633, and 6,308,056.

Because the cable transmission medium provides such a bandwidth rich environment for transmission, service providers are using portions of the bandwidth outside the 50 MHz to 810 MHz TV signal window in order to transmit other signals, such as those used for cable modems. These cable modems are designed to transmit and receive their data signals using carrier signals that lie at a frequency below that of the TV signal band, and hence well below that of RF noise. Frequencies of these carrier signals are chosen such that interference with TV signal within the TV signal band are kept to a minimum. For instance, U.S. Pat. No. 6,341,195 provides an apparatus and methods for a television on-screen guide, where data for the guide is provided using another frequency channel.

End users with big screen TVs, and in some cases projection TVs, will not tolerate a decreased TV signal quality in order to have other services simultaneously provided, such as cable Internet access. Unfortunately, as more and more services are offered on cable, such as telephone or video on demand, the requirement that each of these services have a predetermined carrier frequency that does not interfere with the TV signals and each other, becomes more difficult to satisfy. As a result, more demand is placed in attempting to find suitable carrier frequency for each of these additional services. Determining this suitable carrier frequency results in frequency planning. If there are of a total of N frequencies within a frequency plan with none or few of the frequencies being fixed, then selection of a suitable carrier frequency is facilitated. If there are a large number of fixed carrier frequencies then selection of suitable carriers is more difficult since the existing fixed carriers cannot be varied. Therefore a carrier must be selected which will not cause interference when used along with the existing frequencies. The addition of multiple carrier frequencies to a television broadband signal within a cable results in a limitation on the number of separate frequencies that can be used because of mixing and beating of these carrier signals.

Mixing and beating of the carrier frequencies below the TV signal band results in artifacts that cause interference in the received TV signal for signals within the TV signal band. Of course, services can also be offered at carrier frequencies above the TV signal band, however high-speed electronics are known to be more expensive and typically consumers will not be willing to pay a premium for having additional services that compromise their TV signal quality. It would be advantageous to have a television tuner that allows for increased utilization of bandwidth outside the TV signal band without compromising TV signal quality within the TV signal band.

It is therefore an object of the invention to provide a television tuner that allows for service providers to provide additional services at frequencies below the TV signal transmission band without compromising received TV signal quality.

### SUMMARY OF THE INVENTION

In accordance with the present invention there is provided a dual conversion IF tuner front end having an input port for receiving a RF input signal comprising:

an input filter coupled to the input port for receiving the RF input signal and for filtering a portion of the RF input signal to provide a filtered RF signal, wherein said input filter removes all signals below an input cutoff frequency from the received RF signal when providing said filtered RF signal;

a low noise amplifier coupled to an output port of the input filter for receiving said filtered RF signal, said low noised amplifier passing all channels residing in a television band above said input cutoff frequency;

a first mixer having a first input port coupled to said low noise amplifier and a second input port coupled to a first local oscillator signal, wherein an output signal from an output port on said first mixer is a first IF signal;

a first IF filter having an input port coupled to said first mixer output port for providing coarse channel selection, wherein said first IF filter removes all channels outside a selected frequency band from said first IF signal;

a second mixer having a first input port coupled to an output port of said first IF filter, a second input port coupled to receive a second local oscillator signal, and an output port; and,

a second IF filter having an input port coupled said second mixer output port for providing fine channel selection at an output port thereof.

In accordance with the present invention there is provided a method of receiving a broadband RF signal using a dual conversion IF tuner front end comprising the steps of:

receiving the broadband RF signal having a plurality of frequency channels;

filtering said broadband RF signal, thereby removing all signals below an input cutoff frequency from said RF signal;

amplifying said received RF signal having all signals below the input cutoff frequency removed in a low noise amplifier;

converting said RF signal to a first IF signal comprising substantially all of said plurality of channels;

filtering said first IF signal to remove channels having frequencies outside of a selected band;

converting the filtered first IF signal to a second IF signal; and,

filtering said second IF signals so that only one channel remains in said second IF signal.

In accordance with an aspect of the present invention there is provided a receiver comprising one or more of dual conversion RF tuners front ends, wherein each RF tuner front end comprises:

an input filter coupled to the input port for receiving the RF input signal and for filtering a portion of the RF input signal to provide a filtered RF signal, wherein said input filter removes all signals below an input cutoff frequency from the received RF signal when providing said filtered RF signal;

a low noise amplifier coupled to an output port of the input filter for receiving said filtered RF signal, said low noised amplifier passing all channels residing in a television band above said input cutoff frequency;

a first mixer having a first input port coupled to said low noise amplifier and a second input port coupled to a first local oscillator signal, wherein an output signal from an output port on said first mixer is a first IF signal;

a first IF filter having an input port coupled to said first mixer output port for providing coarse channel selection, wherein said first IF filter removes all channels outside a selected frequency band from said first IF signal;

a second mixer having a first input port coupled to an output port of said first IF filter, a second input port coupled to receive a second local oscillator signal, and an output port; and,

a second IF filter having an input port coupled said second mixer output port for providing fine channel selection at an output port thereof.

According to another aspect of the invention there is provided a receiver coupled to a receiving end of a cable, the receiver absent a transmitter for transmitting on said cable, the receiver comprising: a high pass input filter coupled to an input port of said receiver for providing a filtered signal, said filtered signal including multimedia information for presentation to a user by a multimedia device coupled to said receiver and transmitted from a multimedia source at a transmitting end of the cable and the filtered signal having other than signals transmitted therein from other devices coupled to the receiving end of the cable.

According to another aspect of the invention there is provided a tuner front end comprising: a high pass input filter having an input port coupled to a cable for receiving an RF input signal and for filtering a portion of the RF input signal to provide a filtered RF signal, wherein said filtered RF signal is provided to a multimedia device for extraction of multimedia information from said filtered RF signal for the purpose of presentation of said multimedia information by an end user.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram showing multiple services connected to a cable network;

FIG. 2a is a detailed block diagram of the preferred embodiment of the invention, a dual conversion tuner in accordance with the present invention; and,

FIG. 2b illustrates a filtered RF signal provided to a delayed AGC amplifier.

### DETAILED DESCRIPTION

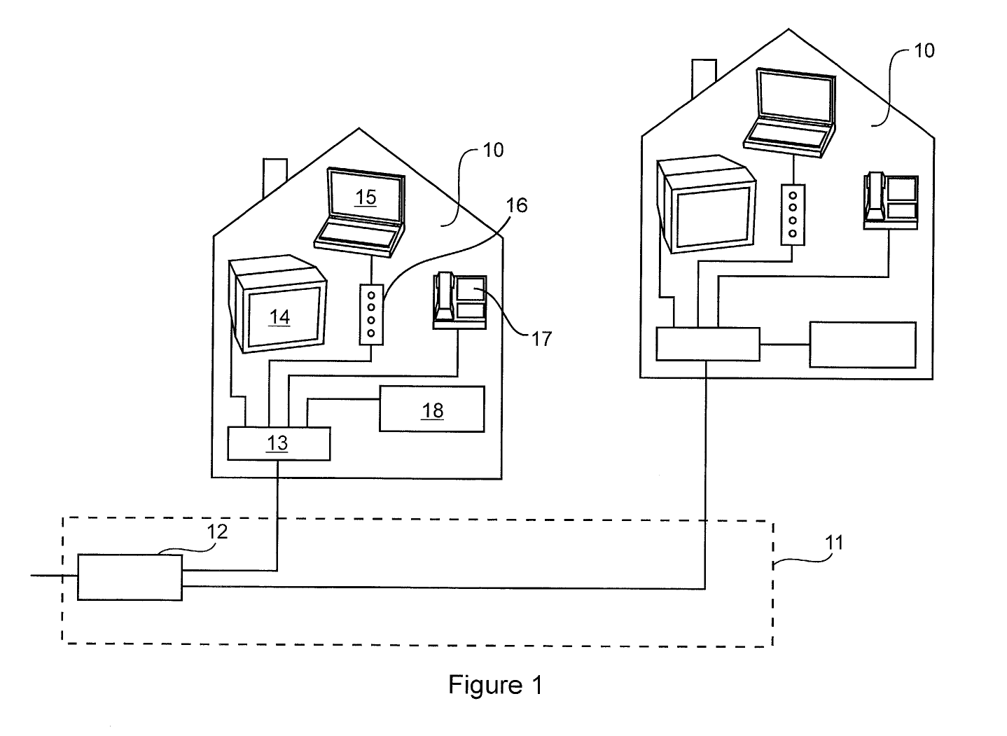

FIG. 1 illustrates houses in a residential area. Each of the houses 10 having multiple services connected to a cable television network 11 provided to each house from a service provider node 12. For instance each of the houses comprises devices that use the cable television network to send and receive RF signals thereon. The equipment in each house is not limited to that shown—a cable modem 16, a telephone 17, a computer 15 and some other device 18 connected to a RF splitter/combiner 13 within the house 10. The splitter/combiner is used for splitting RF signals received along the cable television network 11 to provide a portion of the RF signal to the equipment, as well as to combine RF signals transmitted from the equipment onto the cable television network for processing by the service provider.

The addition of many services to the cable television network is possible because a large bandwidth coaxial cable transmission medium is capable of supporting a large number of carrier frequencies. For instance within each house 10 there is a cable modem 16 which uses bandwidth below the television signal band for sending and receiving of RF signals in order to provide Internet access to the computer 15. A cable telephone 17 also uses RF carrier signal frequencies that reside below the TV signal band. The other device 18 also uses carrier signal frequencies that reside below the TV signal band. As a result there are a large number of carrier frequencies sharing this bandwidth below the TV signal band. Determining suitable carrier frequencies for each of these devices is termed frequency planning. Where the service provider typically determines which carrier frequencies are assigned to specific devices in order to minimize interferences between devices. If there are a total of N frequencies within the frequency plan, with all of the frequencies variable, then planning is a straightforward task for small values of N. If there are a large number of fixed carrier frequencies already within a frequency plan, then selection of suitable new carrier frequencies is more difficult. Thus, for service provision by cable providers, wherein hardware costs are significant and wherein one service is typically added at a time, the addition of each new service renders the potential to add another more remote due to frequency planning issues. Of course, a complex frequency plan could be set up initially before implementation of the first service, but this has not been done. Further, the new services to be added are not necessarily known at the outset of the frequency planning process.

Of course, a simple solution is to re-plan the carrier frequency allocation each time a service is added. Unfortunately, consumers do not wish to purchase new equipment such as televisions, modems, telephones, etc. every time a new service is offered, so as will be evident to those of skill in the art, once a service is roled out, that carrier frequency is very difficult to change or reassign.

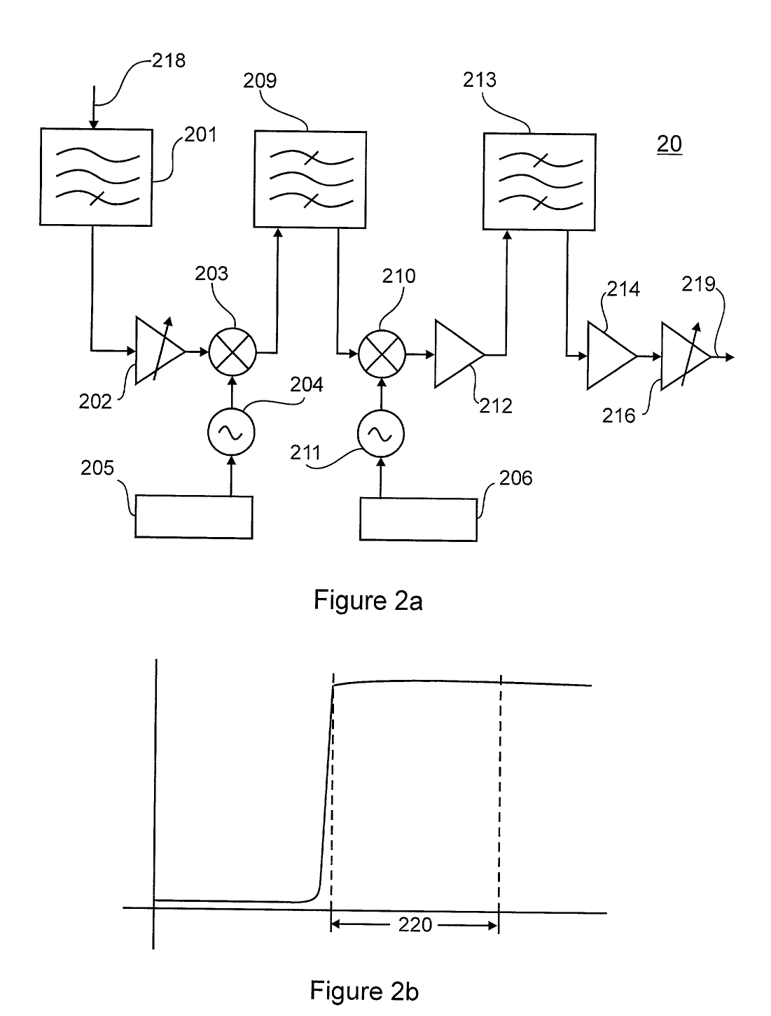

In FIG. 2a a preferred embodiment of a dual conversion tuner front end 20 according to the present invention is shown. RF signals from a cable TV input source are received from the cable television network by the tuner 20 through an input port 218 on a high pass input filter 201 which has low loss (FIG. 2b) across the television frequency band 220. Filter 201 operates to attenuate signals below an input cutoff frequency corresponding to the lowest frequency in the television band according to FIG. 2b. As distinguished from the prior art, filter 201 is not a narrow band-pass tracking filter nor is filter 201 a low-pass filter.

Following filter 201, the RF signal passes through a delayed AGC amplifier 202, which operates in conjunction with IF AGC amplifier 216, to control the overall signal level in tuner 20. Amplifier 202 may be a variable gain amplifier or a variable gain attenuator in series with a fixed gain amplifier. The amplifier 202 comprises a low noise amplifier (LNA) with a high linearity that is sufficient to pass the entire television signal band 220. Amplifier 202 functions to control high input signal levels in the received RF signal. Typically the cable television signals have signal strength of +15 dBmV and may comprise 100 cable channels within the TV signal band. Amplifier 202 regulates the varying signal levels in this TV signal band of received channels.

Mixer 203 receives a RF signal having a controlled level from amplifier 202 and local oscillator 204. A first IF signal is generated in mixer 203 and provided to first IF filter 209. Filter 209 is a band pass filter that provides coarse channel selection in tuner 20. Filter 209 selects a narrow band of channels or even a single channel from the television signals in the first IF signal.

Following IF filter 209, mixer 210 mixes the first IF signal with a second local oscillator signal from local oscillator 211 to generate a second IF signal. Mixer 210 may be an image rejection mixer, if necessary, to reject unwanted image signals. The characteristics of first IF filter 209 will determine whether mixer 210 must provide image rejection. If the image frequencies of the desired channel are adequately attenuated by the first IF filter 209, then mixer 210 may be a standard mixer.

A first synthesizer 205 controls local oscillator 204 and a second synthesizer 206 controls local oscillator 211. The local oscillator frequencies are selected so that the picture carrier of a particular channel in the RF signal will appear at 45.75 MHz in the second IF signal.

In operation, the front end of the tuner 20 receives the entire television band through the input port 218 of filter 201 and amplifier 202. Following mixer 203, the RF input is converted so that a selected channel in the RF signal appears at a first IF frequency that is selected to pass through filter 209. The first IF frequency is then converted to a second IF frequency of 45.75 MHz at an output port of mixer 210. The frequencies of the first and second local oscillator signals will vary depending upon the specific channel in the RF signal that is desired. In the preferred embodiment, the first local oscillator frequency is selected so that mixer 203 performs an up-conversion of the RF signal. Following filter 209, the first IF signal is then down-converted to 45.75 MHz in mixer 210.

Following mixer 210, the second IF signal is further processed by either digital or analog circuits. Second IF filter 213 may be constructed on the same integrated circuit substrate as the other elements of tuner circuit 20 or it may be a discrete off-chip device. When second IF filter 213 is a discrete off-chip element, then amplifiers 212 and 214 are used to provide proper impedances for filter 213 as well as to provide gain to maintain system noise performance. After amplifier 214, the signal either remains on-chip for further processing or it can be provided to an off-chip device, such as a decoder (not shown), through a buffer (not shown).

If the signal is processed on-chip, then the second IF signal passes through IF AGC amplifier 216, which operates in conjunction with delayed AGC amplifier 202, to control the overall tuner gain. An output port 219 is provide on the IF AGC 216 for providing an IF output signal. Of course, filter 209 may be constructed on the same integrated circuit substrate as mixers 203 and 210 or filter 209 may be a discrete off-chip device.

In an alternative embodiment of the present invention, a plurality of tuners 20 are disposed on a single integrated substrate and a single RF input drives the plurality of tuners 20. This allows a single integrated device to concurrently provide different television channels through the output of each tuner. This embodiment could be used to drive a “picture-in-a-picture” display or any other display format that requires multiple tuners. In another alternative embodiment, the plurality of tuners on a single substrate are coupled to independent RF signal sources and provide independent television signals, such as for example an output from a satellite received is coupled to a first tuner and a CATV input is provided a second tuner from the plurality of tuners.

The present invention can be used in applications other than a television receiver disposed within a TV. Tuner 20 can be embodied as part of an “add-in” board or a component of a personal computer. This allows a user to receive and view television signals on the computer's display. The user could also record or capture television programs directly to the computer's memory. The computer could then be used to replay recorded programs or to manipulate or alter selected frames or segments of the captured video and audio signal, or the computer may capture data which may have been imbedded in the video signal.

Furthermore, the present invention will be understood to not be limited to an integrated substrate. Prior art tuners require the use of a narrow-band, tunable filter to eliminate undesired channels from the receiver.

In a television system, signals representing individual channels are assigned to specific frequencies in a defined frequency band. For example, in the United States, television signals are generally transmitted in a band from 55 MHz to 806 MHz. The received RF signals pass through a front-end filter 201. In the preferred embodiment, filter 201 is a high pass filter that is designed to remove all frequencies below an input cutoff frequency. The input cutoff frequency is chosen to be lower than the frequencies of the channels in the television band, and more specifically lower than a lowest frequency within the TV signal band.

Advantageously, the present invention is distinguished over the prior art by allowing all frequencies in RF input signal band to enter the front-end of tuner 20 and undesired low frequencies are removed through high pass filtering of the RF input signal through the use of the high pass filter 201. Thus advantageously removing any RF signals used as carrier signals below the TV signal band. Such that artifacts of these signals will have a much less pronounced effect on a quality of the TV signal within the TV signal band.

It is also apparent to those of skill in the art that the front end employing the high pass filter is not limited to TV tuners and is also applicable to other multimedia devices such as cable radio receivers. Where these multimedia devices are absent a transmitter coupled to the same cable.

Numerous other embodiments may be envisaged without departing from the spirit or scope of the invention.

What is claimed is:

1. A dual conversion IF tuner front end having an input port for receiving a RF input signal comprising:
an input filter coupled to the input port for receiving the RF input signal and for filtering a portion of the RF input signal to provide a filtered RF signal, wherein said input filter removes all signals below an input cutoff frequency from the received RF signal when providing said filtered RF signal;
a low noise amplifier coupled to an output port of the input filter for receiving said filtered RF signal, said low noised amplifier passing all channels residing in a television band above said input cutoff frequency;
a first mixer having a first input port coupled to said low noise amplifier and a second input port coupled to a first local oscillator signal, wherein an output signal from an output port on said first mixer is a first IF signal;
a first IF filter having an input port coupled to said first mixer output port for providing coarse channel selection, wherein said first IF filter removes all channels outside a selected frequency band from said first IF signal;
a second mixer having a first input port coupled to an output port of said first IF filter, a second input port coupled to receive a second local oscillator signal, and an output port; and,
a second IF filter having an input port coupled said second mixer output port for providing fine channel selection at an output port thereof.

2. A dual conversion IF tuner front end according to claim 1, comprising:
a first frequency synthesizer for generating said first local oscillator signal; and, a second frequency synthesizer for generating said second local oscillator signal.

3. A dual conversion IF tuner front end according to claim 2, comprising:
a first amplifier disposed between the second mixer output port and said second IF filter input port for providing an impedance matched signal to said second IF filter.

4. A dual conversion IF tuner front end according to claim 3, comprising:
a second amplifier having an input port coupled to said second IF filter output port, wherein said first and second amplifiers are for providing gain in order to maintain system noise performance.

5. A dual conversion IF tuner front end according to claim 4, wherein said low noise amplifier, said first mixer, said second mixer are physically located on a same integrated circuit substrate.

6. A dual conversion IF tuner front end according to claim 5, wherein said RF input signal is received from a coaxial cable source having an RF signal from a service provider propagating thereon.

7. A dual conversion IF tuner front end according to claim 1, wherein the input filter is a high pass filter.

8. A dual conversion IF tuner front end according to claim 1, wherein the front end is absent another filter for filtering said filtered RF signal prior to amplification by the low noise amplifier

9. A dual conversion IF tuner front end according to claim 1, wherein the input filter and low noise amplifier are integrated on a same substrate.

10. A dual conversion IF tuner front end according to claim 9, wherein components within the tuner are integrated on a same substrate.

11. A method of receiving a broadband RF signal using a dual conversion IF tuner front end comprising the steps of:
receiving the broadband RF signal having a plurality of frequency channels;
filtering said broadband RF signal, thereby removing all signals below an input cutoff frequency from said RF signal;
amplifying said received RF signal having all signals below the input cutoff frequency removed in a low noise amplifier;
converting said RF signal to a first IF signal comprising substantially all of said plurality of channels;
filtering said first IF signal to remove channels having frequencies outside of a selected band;
converting the filtered first IF signal to a second IF signal; and, filtering said second IF signals so that only one channel remains in said second IF signal.

12. A method of receiving a broadband RF signal according to claim 11, comprising the steps of:
generating a first local oscillator signal for use in said converting said RF signal to said first IF signal; and
generating a second local oscillator signal for use in said converting said first IF signal to said second IF signal, wherein said generating steps are performed using first and second synthesizers.

13. A method of receiving a broadband RF signal according to claim 12, wherein said broadband RF signal is received from a coaxial cable source, said RF signal provided by a service provider.

12. A dual conversion IF tuner front end according to claim 11, wherein the step of filtering said broadband RF signal is performed using a high pass filter.

14. A dual conversion IF tuner front end according to claim 11, wherein after the step of filtering the front end is absent another filter for filtering said filtered RF signal prior to the step of amplifying.

15. At A receiver comprising one or more of dual conversion RF tuners front ends, wherein each RF tuner front end comprises:
an input filter coupled to the input port for receiving the RF input signal and for filtering a portion of the RF input signal to provide a filtered RF signal, wherein said input filter removes all signals below an input cutoff frequency from the received RF signal when providing said filtered RF signal;
a low noise amplifier coupled to an output port of the input filter for receiving said filtered RF signal, said low noised amplifier passing all channels residing in a television band above said input cutoff frequency;
a first mixer having a first input port coupled to said low noise amplifier and a second input port coupled to a first local oscillator signal, wherein an output signal from an output port on said first mixer is a first IF signal;
a first IF filter having an input port coupled to said first mixer output port for providing coarse channel selection, wherein said first IF filter removes all channels outside a selected frequency band from said first IF signal;
a second mixer having a first input port coupled to an output port of said first IF filter, a second input port coupled to receive a second local oscillator signal, and an output port; and,
a second IF filter having an input port coupled said second mixer output port for providing fine channel selection at an output port thereof.

16. A receiver according to claim 15, wherein each RF tuner front end is coupled to a same RF signal source, where each of said tuners generates an IF signal and where each IF signal generated by each of said tuners comprises a different channel in said RF signal.

17. A receiver according to claim 15, wherein a plurality of other identical tuner front ends are all constructed on a single substrate.

18. A receiver according to claim 15, wherein said first and second local oscillator signals are generated using first and second synthesizers for each tuner front end from the one or more of dual conversion RF tuners front ends.

19. A receiver according to claim 15, wherein the input filter for each front end is a high pass filter.

20. A receiver according to claim 15, wherein each front end is absent another filter for filtering said filtered RF signal prior to amplification by the low noise amplifier

21. A receiver coupled to a receiving end of a cable, the receiver absent a transmitter for transmitting on said cable, the receiver comprising:
a high pass input filter coupled to an input port of said receiver for providing a filtered signal, said filtered signal including multimedia information for presentation to a user by a multimedia device coupled to said receiver and transmitted from a multimedia source at a transmitting end of the cable and the filtered signal having other than signals transmitted therein from other devices coupled to the receiving end of the cable.

22. A tuner front end comprising:
a high pass input filter having an input port coupled to a cable for receiving an RF input signal and for filtering a portion of the RF input signal to provide a filtered RF signal, wherein said filtered RF signal is provided to a multimedia device for extraction of multimedia information from said filtered RF signal for the purpose of presentation of said multimedia information by an end user.
